(19) United States
(12) Patent Application Publication
(10) Pub. No.: US 2024/0414869 A1
(43) Pub. Date: Dec. 12, 2024

(54) HOLDER FOR STACKED COMPRESSION ATTACHED MEMORY MODULES

(71) Applicant: DELL PRODUCTS L.P., Round Rock, TX (US)

(72) Inventors: Arnold Thomas Schnell, Hutto, TX (US); Jing-Tang Wu, Xizhi District (TW); Spike Tzeng, KeeLung City (TW)

(21) Appl. No.: 18/332,075

(22) Filed: Jun. 9, 2023

(51) Int. Cl. H05K 7/14; H05K 9/00

(52) U.S. Cl. CPC H05K 7/1427; H05K 9/0015; H05K 9/0084

(57) ABSTRACT

A holder for stacked compression attached memory modules (CAMMs) includes an outer frame, a first recessed area for receiving a bottom one of the stacked CAMMs, a second recessed area for receiving a top one of the stacked CAMMs, and a metal plate assembly affixed within the outer frame and situated between the first recessed area and the second recessed area.

### FIELD OF THE DISCLOSURE

This disclosure generally relates to information handling systems, and more particularly relates to a holder for stacked compression attached memory modules (CAMMs).

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

A holder for stacked compression attached memory modules (CAMMs) may include an outer frame, a first recessed area for receiving a bottom one of the stacked CAMMs, a second recessed area for receiving a top one of the stacked CAMMs, and a metal plate assembly affixed within the outer frame and situated between the first recessed area and the second recessed area.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1A is a top view of an information handling system as is known in the prior art;

FIG. 1B is a side view of the information handling system of FIG. 1A;

FIG. 1C is a cross-sectional view of the information handling system taken along line A-A in FIG. 1A;

FIG. 2A is a perspective view of a bottom of a CAMM holder according to an embodiment of the current disclosure;

FIG. 2B is a perspective view of a top of the CAMM holder of FIG. 2A;

FIG. 3A is a perspective view of a bottom of a metal plate assembly according to an embodiment of the current disclosure;

FIG. 3B is a perspective view of a top of the metal plate assembly of FIG. 3A;

FIG. 4 is a diagram illustrating a CAMM holder assembly including the CAMM holder of FIGS. 2A and 2B and the metal plate assembly of FIGS. 3A and 3B;

FIG. 5 is an exploded perspective view of an information handling system according to an embodiment of the current disclosure; and

FIG. 6 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

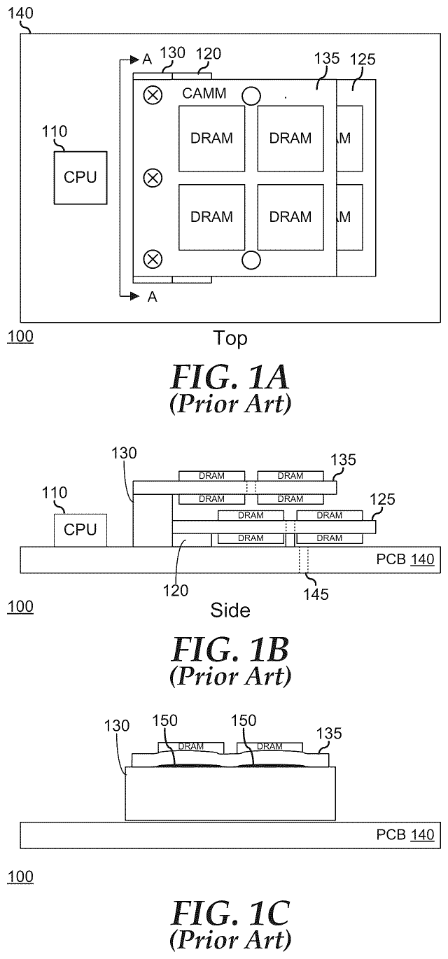

FIG. 1A illustrates an information handling system 100 as may be known in the prior art. Information handling system 100 includes a processor 110, and a compression connector 120 assembled onto a printed circuit board (PCB) 140, and a compression connector 130 assembled onto the PCB. Compression connector 130 is located proximate to processor 110 and compression connector 120 is located further from the processor and adjacent to compression connector 130. Compression connector 120 is populated with a compression attached memory module (CAMM) which includes memory devices populated on a CAMM PCB 125, and compression connector 130 is populated with a CAMM which includes memory devices populated on a CAMM PCB 135. Due to the locations of compression connectors 120 and 130, the configuration of information handling system 100 is said to include “stacked” CAMMs, with CAMM PCB 120 located partially under CAMM PCB 130.

Compression connectors 120 and 130 represents z-axis, or “vertical,” compression connectors that provide stand-offs from PCB 140. Compression connectors 120 and 130 include separate metal contact elements on a top surface of the compression connector, one for each signal line and power line. CAMM PCBs 125 and 135 each include surface contact connections that are compressed to engage with the contact elements of respective compression connectors 120 and 130. Examples of compression connectors may include cStack or mezzanine-type connectors from Amphenol, PCBeam connectors from Neoconix, or the like.

The memory devises on CAMM PCBs 125 and 135 represent fifth generation DDR (DDR5) memory devices. In a typical case, PCB 140 is configured with an interface pad arrangement to accommodate a single compression connector and a dual-channel DDR5 CAMM (not illustrated). However, in the current example, the single interface pad arrangement is utilized to accommodate compression connectors 120 and 130, and each of the compression connectors is arranged to carry only one of the two (2) DDR5 channels. As such the memory devices on each of CAMM PCBs 125 and 135 are accessed by CPU 110 via only one of the first memory channel or the second memory channel. In this case, they use stackable CAMMs that each only utilize one of the DDR5 memory channels may be based upon a design choice to provide a low-cost design. In this embodiment, compression connectors 120 and 130 still include contact elements associated only one memory channel, and the memory devices on CAMM PCBs 125 and 135 are configured to utilize only one of the memory channels.

FIG. 1B shows that CAMM PCB 135 is affixed to compression connector 130 by three (3) screws. Such a mechanism for attaching CAMM PCB 135 to compression connector 130 may include other elements, as needed or desired. While not directly illustrated CAMM PCB 125, due to the extended length of the CAMM PCB, is affixed to compression connector 120 by three (35) screws, similar to CAMM PCB 135, and by an additional two (2) screws to PCB 140 to support the extended length of the CAMM PCB. Due to the presence of CAMM PCB 125 below CAMM PCB 135, there is no way to support the extended length of CAMM PCB 135. Compression connectors 120 and 130, and PCB 140 may include through-holes through which the screws pass, and bolts may be affixed to the screws on the bottom side of the PCB, as needed or desired. The attachment mechanism may include a bolster on the bottom side of PCB 130, as needed or desired.

FIG. 1C shows a particular case where CAMM PCB 135 exhibits a deformation under the compression applied by the screws. In this case, the deformation results in voids 150 where the contact between compression connector 130 and CAMM PCB 135 may become degraded, resulting in poor signal quality between CPU 110 and the memory devices on the CAMM PCB, and the resulting data errors can cause a system crash of information handling system 100. This condition may be exacerbated by the lack of screws to support the extended length of CAMM PCB 135. While hidden by compression connector 130, CAMM PCB 125 may be understood to exhibit similar deformation with respect to compression connector 120, with the associated degradation in signal quality between CPU 110 and the memory devices on the CAMM PCB.

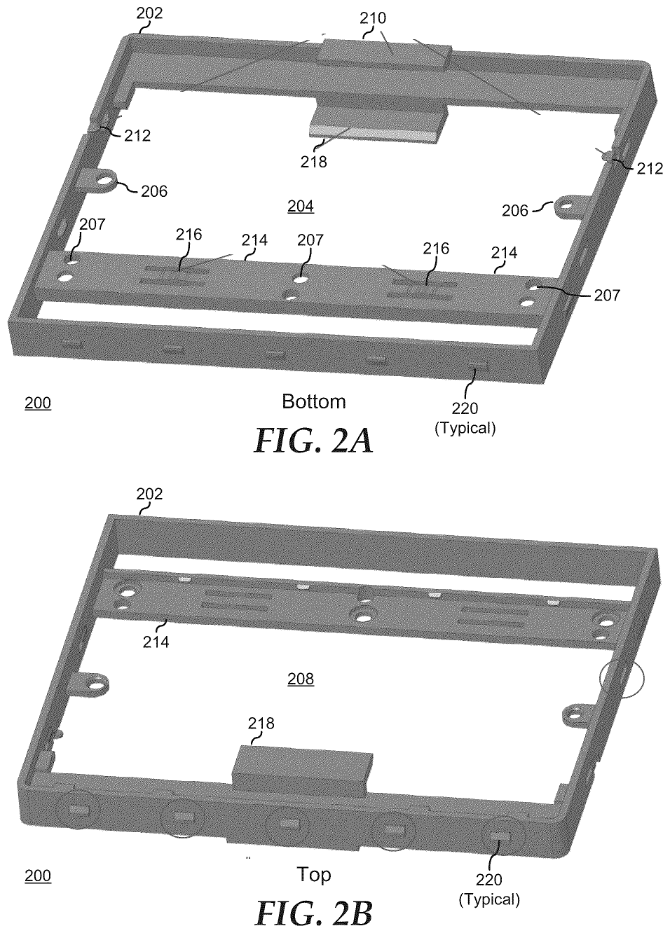

The current disclosure provides a mechanism for mounting stacked CAMMs in an information handling system. The mounting mechanism resolves the issues of deformation of CAMM PCBs and the lack of support for the extended length of a top CAMM PCB in stack as described above. FIG. 2A illustrates a bottom view of a stacked CAMM holder 200, and FIG. 2B illustrates a top view of the CAMM holder. CAMM holder 200 includes an outer frame 202 which encloses a bottom recessed area 204 for receiving a lower one of the stacked CAMMs, and at top recessed area 208 for receiving an upper one of the stacked CAMMs. The bottom CAMM is retained within frame 202 by a bottom CAMM retention flange 210 situated to retain the edge of the bottom CAMM that is opposite from the compression connector signal pad array of the bottom CAMM, and bottom CAMM retention tabs 212 situated to lock the bottom CAMM into the CAMM holder by the edges of the bottom CAMM. CAMM holder 200 further includes a spine 214 that corresponds with the edge of the bottom CAMM that includes the compression connector signal pad array. Frame 202 includes two (2) bottom CAMM screw mounts 206 to retain extended length CAMMS, and spine 214 includes three (3) screw holes 207 for the three (3) mounting screws associated with the bottom compression connector.

When the bottom CAMM is installed into holder 200, the resulting assembly can be turned over and affixed through the bottom compression connector to an information handling system. The bottom compression connector is affixed to the PCB of the information handling system, the assemblage of CAMM holder 200 and the bottom CAMM is placed on the bottom compression connector, and three (3) screws are affixed through the PCB in screw holes 207 and two (2) screws are affixed through the PCB in bottom CAMM screw mounts 206 if the bottom CAMM has an extended length. Thus spine 214 transfers the compression applied at the screw holes to the compression connection between the bottom CAMM and the bottom compression connector. Spine 214 includes detent structures 216 that provide a prestressed downward deformation of the installed bottom CAMM toward the bottom compression connector, such that, when the screws are tightened, the tendency of the bottom CAMM PCB is to remain flat and firmly coupled electrically and mechanically with the bottom compression connector.

The extent of detent structures 216 on beam 214, or of the depth of the m-shape of beam 310 may be designed to provide a desired amount of prestress on the CAMM PCB, as needed or desired. While being described as having detent structures 216, a spine similar to spine 214 may have other shapes configured to provide a prestressed downward deformation of the captured CAMM PCB, such as an m-shape, an arch-shape, a v-shape, or the like. The extent of detent structures 216 on beam 214, or of the depth of other structures may be designed to provide a desired amount of prestress on the CAMM PCB, as needed or desired. Holder 200 further includes a top CAMM retention flange 218 situated to retain the edge of the top CAMM that is opposite from the compression connector signal array of the top CAMM. Finally, CAMM holder 200 includes a number of metal plate retention tabs 220 situated around the four (4) edges of the CAMM holder, as described further below.

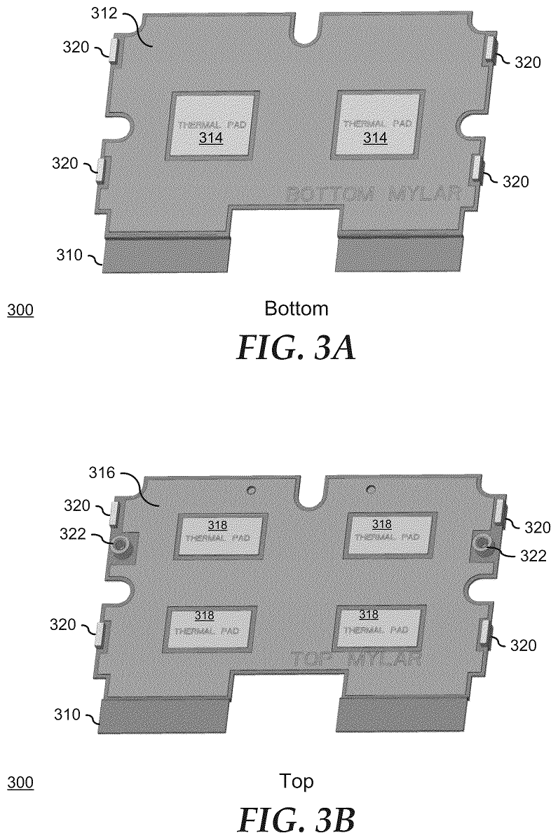

FIG. 3A illustrates a bottom view of a metal plate assembly 300, and FIG. 3B illustrates a top view of the metal plate assembly. Metal plate assembly 300 is disposed within CAMM holder 200 as described further below, and provides for shielding against electromagnetic interference (EMI) between the bottom CAMM and the top CAMM, and also provides a thermal mass for the dissipation of heat generated by the memory devices on the top and bottom CAMMs. Metal plate assembly 300 includes a metal plate 310 that provides the EMI shielding and the thermal mass. The bottom side of metal plate 310 is covered with a bottom Mylar film 312 with cut-outs for thermal pads 314 that are affixed to the bottom of the metal plate. The top side of metal plate 310 is covered with a top Mylar film 316 with cut-outs for thermal pads 318 that are affixed to the top of the metal plate. The sizes and locations of the cutouts within bottom and top Mylar films 312 and 316, and of bottom and top thermal pads 314 and 318 may be determined based upon the configuration of the memory devices situated on the top and bottom CAMMs. Thus a number of differently configured metal plate assemblies may be needed to accommodate the different configurations of commercially available CAMMs, as needed or desired.

Metal plate 310 is affixed with one or more metallic gaskets 320 that are configured to provide an electrical connection between a ground plane of the information handling system and a cover for the stacked CAMMs, as described further below, for the EMI shielding function of metal plate assembly 300. The top side of metal plate 310 further includes nuts 322 that are provided to accommodate the two (2) additional screws for the extended length of the top CAMM.

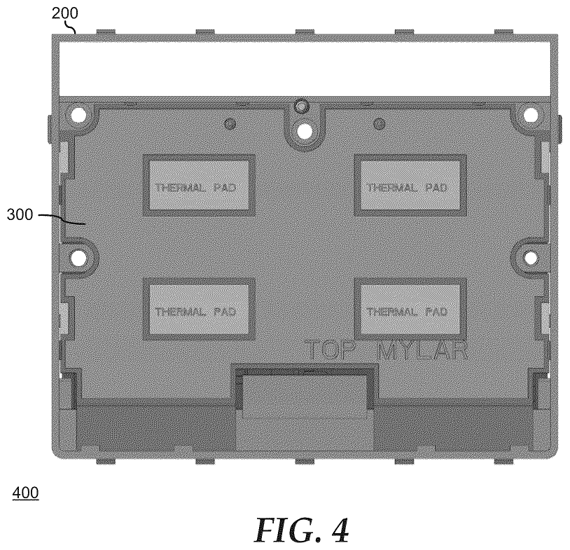

FIG. 4 illustrates a CAMM holder assembly 400 that includes CAMM holder 200 and metal plate assembly 300. In a particular embodiment, metal plate assembly 300 is installed into the bottom of CAMM holder 200 and metal plate retention tabs 220 are located so as to retain the metal plate assembly in the bottom of the CAMM holder. Here, metal plate assembly 300 is installed into CAMM holder 200 prior to the installation of the bottom CAMM. In another embodiment, metal plate assembly 300 is installed into the top of CAMM holder 200 and metal plate retention tabs 220 are located so as to retain the metal plate assembly to in the top of the CAMM holder. Here, metal plate assembly 300 is installed into CAMM holder 200 prior to the installation of the top CAMM.

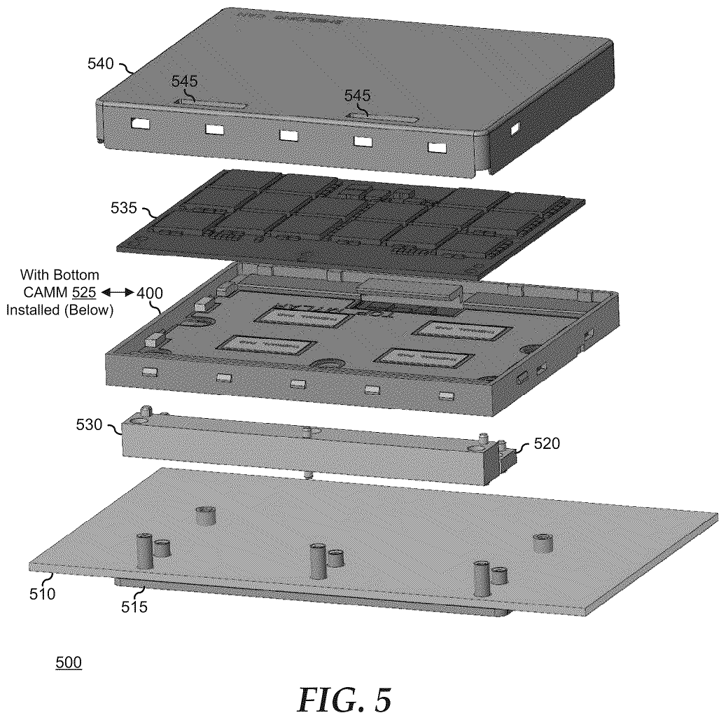

FIG. 5 shows an information handling system 500 including a PCB 510, a bottom compression connector 520, a top compression connector 530, a CAMM holder assembly 400 including a bottom CAMM 525 installed in the bottom side of the CAMM holder assembly, a top CAMM 535, and a shielding cover 540. PCB 510 is fitted with a bolster assembly 515 to the bottom side of the PCB. Bolster assembly 515 includes eight (8) studs to receive attachment screws to affix the CAMMs to the PCB. Three (3) of the studs are associated with top compression connector 530, three (3) of the studs are associated with bottom compression connector 520, and two (2) of the studs are provided for retention of the extended length of the bottom CAMM.

In an exemplary assembly flow for information handling system 500, bottom CAMM 235 is installed into CAMM holder assembly 400. Then bottom compression connector 520 is affixed to PCB 510, and bottom CAMM 525, as assembled with CAMM holder assembly 400, is screwed by the associated five (5) screws to the associated studs of bolster 515. Note here that bolster 515 may be configured to be electrically connected to a ground plane of PCB 510, and so, the two (2) screws associated with the extended length of bottom CAMM 525 may configured to be screwed through metal plate 310 of metal plate assembly 300 to connect the metal plate to the ground plane. In this way, metal plate 310 operates to provide EMI shielding for bottom CAMM 525 and for top CAMM 535. Next, top compression connector 530 is affixed to PCB 510 and top CAMM 535 is installed into CAMM holder assembly 400 and is crewed by the associated three (3) crews to the associated studs of bolster 515.

An additional two (2) screws associated with the extended length of top CAMM 535 are screwed into studs 322 of metal plate assembly 300 to firmly attach the top CAMM to CAMM holder assembly 400. Finally, shielding cover 540 is installed over CAMM holder assembly 400 to provide EMI shielding for the entire CAMM assembly. In this regard, metallic gaskets 322 provide for an electrical connection between metal plate assembly 300 and shielding cover 540, as needed or desired to provide the EMI shielding for bottom and top CAMMS 525 and 535. Shielding cover 540 detent structures 545 that provide a prestressed downward deformation of the installed top CAMM toward the top compression connector, such that, when the shielding cover is affixed to CAMM holder assembly 400, the tendency of top CAMM 535 is to remain flat and firmly coupled electrically and mechanically with top compression connector 530, thereby counteracting the deformation of the top CAMM PCB.

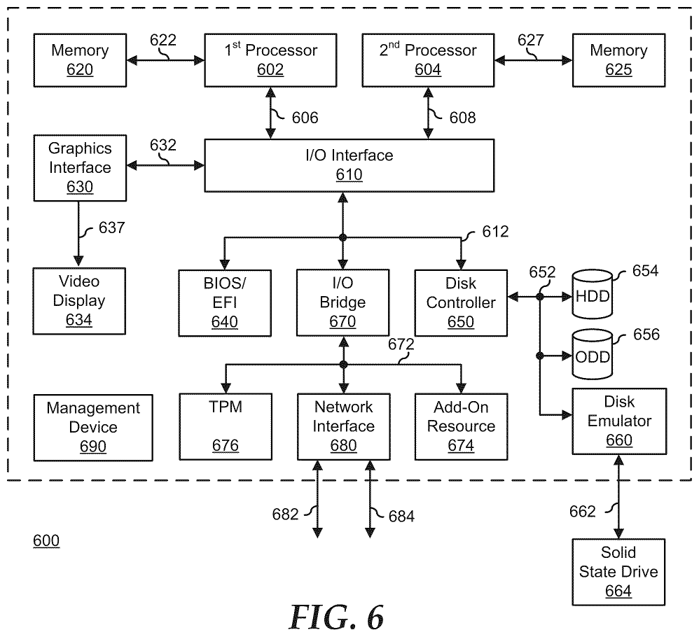

FIG. 6 illustrates a generalized embodiment of an information handling system 600 similar to information handling system 60. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 600 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 600 can include processing resources for executing machine-executable code, such as a central processing unit (CPU), a programmable logic array (PLA), an embedded device such as a System-on-a-Chip (SoC), or other control logic hardware. Information handling system 600 can also include one or more computer-readable medium for storing machine-executable code, such as software or data. Additional components of information handling system 600 can include one or more storage devices that can store machine-executable code, one or more communications ports for communicating with external devices, and various input and output (I/O) devices, such as a keyboard, a mouse, and a video display. Information handling system 600 can also include one or more buses operable to transmit information between the various hardware components.

Information handling system 600 can include devices or modules that embody one or more of the devices or modules described below, and operates to perform one or more of the methods described below. Information handling system 600 includes a processors 602 and 604, an input/output (I/O) interface 610, memories 620 and 625, a graphics interface 630, a basic input and output system/universal extensible firmware interface (BIOS/UEFI) module 640, a disk controller 650, a hard disk drive (HDD) 654, an optical disk drive (ODD) 656, a disk emulator 660 connected to an external solid state drive (SSD) 662, an I/O bridge 670, one or more add-on resources 674, a trusted platform module (TPM) 676, a network interface 680, a management device 690, and a power supply 695. Processors 602 and 604, I/O interface 610, memory 620, graphics interface 630, BIOS/UEFI module 640, disk controller 650, HDD 654, ODD 656, disk emulator 660, SSD 662, I/O bridge 670, add-on resources 674, TPM 676, and network interface 680 operate together to provide a host environment of information handling system 600 that operates to provide the data processing functionality of the information handling system. The host environment operates to execute machine-executable code, including platform BIOS/UEFI code, device firmware, operating system code, applications, programs, and the like, to perform the data processing tasks associated with information handling system 600.

In the host environment, processor 602 is connected to I/O interface 610 via processor interface 606, and processor 604 is connected to the I/O interface via processor interface 608. Memory 620 is connected to processor 602 via a memory interface 622. Memory 625 is connected to processor 604 via a memory interface 627. Graphics interface 630 is connected to I/O interface 610 via a graphics interface 632, and provides a video display output 636 to a video display 634. In a particular embodiment, information handling system 600 includes separate memories that are dedicated to each of processors 602 and 604 via separate memory interfaces. An example of memories 620 and 630 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 640, disk controller 650, and I/O bridge 670 are connected to I/O interface 610 via an I/O channel 612. An example of I/O channel 612 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 610 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 640 includes BIOS/UEFI code operable to detect resources within information handling system 600, to provide drivers for the resources, initialize the resources, and access the resources. BIOS/UEFI module 640 includes code that operates to detect resources within information handling system 600, to provide drivers for the resources, to initialize the resources, and to access the resources.

Disk controller 650 includes a disk interface 652 that connects the disk controller to HDD 654, to ODD 656, and to disk emulator 660. An example of disk interface 652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 660 permits SSD 664 to be connected to information handling system 600 via an external interface 662. An example of external interface 662 includes a USB interface, an IEEE 1394 (Firewire) interface, a proprietary interface, or a combination thereof. Alternatively, solid-state drive 664 can be disposed within information handling system 600.

I/O bridge 670 includes a peripheral interface 672 that connects the I/O bridge to add-on resource 674, to TPM 676, and to network interface 680. Peripheral interface 672 can be the same type of interface as I/O channel 612, or can be a different type of interface. As such, I/O bridge 670 extends the capacity of I/O channel 612 when peripheral interface 672 and the I/O channel are of the same type, and the I/O bridge translates information from a format suitable to the I/O channel to a format suitable to the peripheral channel 672 when they are of a different type. Add-on resource 674 can include a data storage system, an additional graphics interface, a network interface card (NIC), a sound/video processing card, another add-on resource, or a combination thereof. Add-on resource 674 can be on a main circuit board, on separate circuit board or add-in card disposed within information handling system 600, a device that is external to the information handling system, or a combination thereof.

Network interface 680 represents a NIC disposed within information handling system 600, on a main circuit board of the information handling system, integrated onto another component such as I/O interface 610, in another suitable location, or a combination thereof. Network interface device 680 includes network channels 682 and 684 that provide interfaces to devices that are external to information handling system 600. In a particular embodiment, network channels 682 and 684 are of a different type than peripheral channel 672 and network interface 680 translates information from a format suitable to the peripheral channel to a format suitable to external devices. An example of network channels 682 and 684 includes InfiniBand channels, Fibre Channel channels, Gigabit Ethernet channels, proprietary channel architectures, or a combination thereof. Network channels 682 and 684 can be connected to external network resources (not illustrated). The network resource can include another information handling system, a data storage system, another network, a grid management system, another suitable resource, or a combination thereof.

Management device 690 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 600. In particular, management device 690 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 600, such as system cooling fans and power supplies. Management device 690 can include a network connection to an external management system, and the management device can communicate with the management system to report status information for information handling system 600, to receive BIOS/UEFI or system firmware updates, or to perform other task for managing and controlling the operation of information handling system 600. Management device 690 can operate off of a separate power plane from the components of the host environment so that the management device receives power to manage information handling system 600 when the information handling system is otherwise shut down. An example of management device 690 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 690 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A holder for stacked compression attached memory modules (CAMMs), the holder comprising:
an outer frame;
a first recessed area for receiving a bottom one of the stacked CAMMs;
a second recessed area for receiving a top one of the stacked CAMMs; and
a metal plate assembly affixed within the outer frame and situated between the first recessed area and the second recessed area.

2. The holder of claim 1, further comprising:
a spine located within the outer frame at an end of the bottom CAMM adjacent to a contact pad array of the bottom CAMM of a bottom CAMM printed circuit board (PCB) of the bottom CAMM.

3. The holder of claim 2, wherein, when the bottom CAMM is installed into the holder and installed into an information handling system, the spine transfers compression applied to the spine to limit deformation of the bottom CAMM PCB.

4. The holder of claim 3, wherein the spine includes a detent structure to provide a prestress to the bottom CAMM PCB.

5. The holder of claim 1, wherein the metal plate assembly is configured to provide electromagnetic interference (EMI) shielding for the bottom CAMM and the top CAMM.

6. The holder of claim 5, further comprising:
a cover coupled to the metal plate assembly to further provide the EMI shielding.

7. The holder of claim 6, wherein the metal plate assembly includes a metallic gasket configured to couple the metallic plate assembly to the cover.

8. The holder of claim 6, wherein when the top CAMM is installed into the holder and installed into an information handling system, the cover is configured to limit deformation of the top CAMM PCB.

9. The holder of claim 6, wherein the cover includes a detent structure to provide a prestress to the top CAMM PCB.

10. A method, comprising:
providing, for a holder for stacked compression attached memory modules (CAMMs), an outer frame;
providing, for the holder, a first recessed area for receiving a bottom one of the stacked CAMMs;
providing, for the holder, a second recessed area for receiving an top one of the stacked CAMMs; and
providing, for the holder, a metal plate assembly affixed within the outer frame and situated between the first recessed area and the second recessed area.

11. The method of claim 10, further comprising providing a spine located within the outer frame at an end of the bottom CAMM adjacent to a contact pad array of the bottom CAMM of a bottom CAMM printed circuit board (PCB) of the bottom CAMM.

12. The method of claim 11, wherein, when the bottom CAMM is installed into the holder and installed into an information handling system, the spine transfers compression applied to the spine to limit deformation of the bottom CAMM PCB.

13. The method of claim 12, wherein the spine includes a detent structure to provide a prestress to the bottom CAMM PCB.

14. The method of claim 10, wherein the metal plate assembly is configured to provide electromagnetic interference (EMI) shielding for the bottom CAMM and the top CAMM.

15. The method of claim 14, further comprising providing a cover coupled to the metal plate assembly to further provide the EMI shielding.

16. The method of claim 15, wherein the metal plate assembly includes a metallic gasket configured to couple the metallic plate assembly to the cover.

17. The method of claim 15, wherein when the top CAMM is installed into the holder and installed into an information handling system, the cover is configured to limit deformation of the top CAMM PCB.

18. The method of claim 15, wherein the cover includes a detent structure to provide a prestress to the top CAMM PCB.

19. An information handling system, comprising:
a first compression attached memory module (CAMM);
a second CAMM; and
a holder for affixing the first CAMM and the second CAMM to the information handling system, the holder including:
an outer frame;
a first recessed area for receiving the first CAMM;
a second recessed area for receiving the second CAMM; and
a metal plate assembly affixed within the outer frame and situated between the first recessed area and the second recessed area.

20. The holder of claim 19, further comprising:
a spine located within the outer frame at an end of the bottom CAMM adjacent to a contact pad array of the first CAMM of a first CAMM printed circuit board (PCB) of the first CAMM; and
a cover configured to limit deformation of a second CAMM PCB of the second CAMM.
